(19) United States
(12) Patent Application Publication
(10) Pub. No.: US 2026/0368592 A1
(43) Pub. Date: Nov. 19, 2026

(54) SYSTEMS AND METHODS FOR TUNING CAPACITANCE OF QUBITS

(71) Applicant: D-WAVE SYSTEMS INC., Burnaby (CA)

(72) Inventors: Reza Molavi, North Vancouver (CA); Mark H. Volkmann, Burnaby (CA); Emile M. Hoskinson, Vancouver (CA); Richard G. Harris, North Vancouver (CA); Trevor M. Lanting, Vancouver (CA); Paul I. Bunyk, Pt. Roberts, WA (US); Andrew J. Berkley, Vancouver (CA)

(21) Appl. No.: 19/655,282

(22) Filed: Apr. 22, 2026

Related U.S. Application Data
(63) Continuation of application No. 17/786,192, filed on Dec. 15, 2020, now Pat. No. 12,632,760.
(60) Provisional application No. 62/951,738, filed on Dec. 20, 2019.

(51) Int. Cl. G06N 10/40; G06F 30/347; G06F 30/392; G06F 30/394; H10N 60/12

(52) U.S. Cl. CPC G06N 10/40; H10N 60/12; G06F 30/347; G06F 30/392; G06F 30/394

(57) ABSTRACT

An analog computing system having a qubit which is provided with inductors positioned near to the qubit's Josephson junctions and inductors positioned far from the qubit's Josephson junctions. The near inductors exhibit capacitance-reducing behavior and the far inductors exhibit capacitance-increasing behavior as their respective inductances are increased. Near and far inductors can be tuned to homogenize the capacitance of the qubit across a range of programmable states based on predicted and target capacitance for the qubit. The inductors may be tuned to homogenize both capacitance and inductance.

### FIELD

This disclosure generally relates to analog computing, and particularly to the design and operation of devices for tuning the physical characteristics of quantum devices.

### BACKGROUND

### Quantum Devices

Quantum devices are structures in which quantum mechanical effects are observable. Quantum devices include circuits in which current transport is dominated by quantum mechanical effects. Such devices include spintronics, where electronic spin is used as a resource, and superconducting circuits. A superconducting circuit is a circuit that includes a superconducting device. A superconducting device is a device that includes a superconducting material. A superconducting material is a material that has no electrical resistance below critical levels of current, magnetic field and temperature. Both spin and superconductivity are quantum mechanical phenomena. Superconductivity is a physical phenomenon that was well known in the art at the time of filing of the present application. Quantum devices can be used for measurement instruments, in computing machinery, and the like.

### Quantum Computation

Quantum computation and quantum information processing are active areas of research and define classes of vendible products. A quantum computer is a system that makes direct use of at least one quantum-mechanical phenomenon, such as, superposition, tunneling, and entanglement, to perform operations on data. The elements of a quantum computer are quantum binary digits, known as qubits. Quantum computers hold the promise of providing exponential speedup for certain classes of computational problems such as computational problems simulating quantum physics. Useful speedup may exist for other classes of problems.

One model of quantum computing is adiabatic quantum computing. Adiabatic quantum computing can be suitable for solving hard optimization problems, for example. Further details on adiabatic quantum computing systems, methods, and apparatus are described, for example, in U.S. Pat. Nos. 7,135,701 and 7,418,283.

### Quantum Annealing

Quantum annealing is a computational method that may be used to find a low-energy state of a system, typically preferably the ground state of the system. Similar in concept to classical simulated annealing, the method relies on the underlying principle that natural systems tend towards lower energy states because lower energy states are more stable. While classical annealing uses classical thermal fluctuations to guide a system to a low-energy state, quantum annealing may use quantum effects, such as quantum tunneling, as a source of delocalization to reach an energy minimum more accurately and/or more quickly than classical annealing. In quantum annealing, thermal effects and other noise may be present. The final low-energy state may not be the global energy minimum.

Adiabatic quantum computation may be considered a special case of quantum annealing. In adiabatic quantum computation, the system ideally begins and remains in its ground state throughout an adiabatic evolution. Thus, those of skill in the art will appreciate that quantum annealing systems and methods may generally be implemented on an adiabatic quantum computer. Throughout the present application, any reference to quantum annealing is intended to encompass adiabatic quantum computation unless the context requires otherwise.

### Superconducting Qubits

A quantum processor can be a superconducting quantum processor that includes superconducting qubits. Wendin G. and Shumeiko V. S., “SUPERCONDUCTING QUANTUM CIRCUITS, QUBITS AND COMPUTING” (arXiv: cond-mat/0508729v1, 2005), provides an introduction to the physics and principles of operation of quantized superconducting electrical circuits for quantum information processing.

### Coupling

Couplers can provide communicative coupling between quantum devices in a quantum processor. Coupling can be, for example, between adjacent and/or non-adjacent qubits. Unless expressly indicated otherwise, as used herein and in the claims, the terms couple, couples, coupling and variations of such means direct or indirect communicative coupling or communications between two or more components.

### Tuning Qubit Characteristics

Quantum devices, such as qubits and couplers, may possess various characteristics, such as flux, persistent current, inductance, capacitance, and so on. Such characteristics can affect the results of quantum computations performed by such qubits, and so it can be desirable to tune one or more of those characteristics to align with the parameters of a given computation. Example systems and methods for tuning qubit characteristics, including example qubits and couplers, are provided by U.S. Pat. Nos. 8,536,566 and 9,152,923 and PCT Application No. US2018/066613.

It is advantageous for qubits in an analog computing system, such as a quantum processor, to possess identical (or approximately identical) properties such as inductance and capacitance. This assists in accurately mapping from a problem (e.g. represented as a Hamiltonian) onto a physical analog processor. To that end, some analog processors include a device called an L-tuner for tuning the inductance of a qubit (e.g. as described by U.S. Pat. No. 8,536,566). Adding a “C-tuner” for tuning capacitance has proved challenging due to various factors, such as structural complexity, consequent bandwidth limitations, interference with flux qubit eigenstates, operational flexibility, and/or other factors. There thus continues to be a desire for systems and methods for tuning capacitance of qubits.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

Aspects of the present disclosure provide an analog computing system comprising a qubit. The qubit comprises a qubit loop formed by a first superconducting current path and at least one Josephson junction interrupting the qubit loop. The at least one Josephson junction has a critical distance such that adding a lumped inductance nearer than the critical distance to the at least one Josephson junction along the qubit loop decreases a qubit capacitance at the at least one Josephson junction and adding the lumped inductance further than the critical distance from the at least one Josephson junction along the qubit loop increases the qubit capacitance. The qubit further comprises a plurality of inductors disposed along the qubit loop. Each of the plurality of inductors is tunable to provide a tunable inductance. The plurality of inductors comprises one or more near inductors, each near inductor disposed along the qubit loop less than the critical distance from the at least one Josephson junction, and one or more far inductors, each far inductor disposed along the qubit loop more than the critical distance from the at least one Josephson junction.

In some implementations, the analog computing system comprises one or more couplers tunably coupleable to the qubit loop. Each of the one or more couplers is tunable to provide a respective coupling strength with the qubit.

In some implementations, the tunable inductance for each of the plurality of inductors is tunable within a corresponding inductance range and each of the one or more couplers has a corresponding coupler-induced inductance range, each coupler-induced inductance range comprising a difference in a qubit inductance at the at least one Josephson junction between states of the corresponding one of the one or more couplers, and a sum of the tunable inductance ranges of the plurality of inductors is greater than each of the corresponding coupler-induced inductance ranges.

In some implementations, one inductor of the plurality of inductors comprises one or more inductor Josephson junctions interrupting the qubit loop and tunable to provide a respective tunable inductance range of the one inductor of the plurality of inductors. In some implementations, the one of the plurality of inductors comprises one or more DC-SQUIDs, the one or more DC-SQUIDs comprising the one or more inductor Josephson junctions. In some implementations, the one of the plurality of inductors comprises a plurality of DC-SQUIDs connected in series along the qubit loop.

In some implementations, the sum of the tunable inductance ranges of the plurality of inductors is greater than a total coupler-induced inductance range, the total coupler-induced inductance range comprising a difference between a first coupler-induced inductance and a second coupler-induced inductance, the first coupler-induced inductance comprising the qubit inductance in a first state where each of the one or more couplers is ferromagnetically coupled to the qubit and the second coupler-induced inductance comprising the qubit inductance in a second state where each of the one or more couplers is anti-ferromagnetically coupled to the qubit.

In some implementations, the one or more near inductors collectively are tunable to reduce the qubit capacitance from a first coupler-induced capacitance to within a first threshold of a target capacitance; and the one or more far inductors collectively are tunable to increase the qubit capacitance from a second coupler-induced capacitance to within a second threshold of the target capacitance.

In some implementations, the first coupler-induced capacitance comprises the qubit capacitance in a third state where each of the one or more couplers that is nearer to the at least one Josephson junction along the qubit loop than the critical distance, if any, is anti-ferromagnetically coupled to the qubit loop and each of the one or more couplers that is farther from the at least one Josephson junction along the qubit loop than the critical distance, if any, is ferromagnetically coupled to the qubit loop; and the second coupler-induced capacitance comprises the qubit capacitance in a fourth state where each of the one or more couplers that is nearer to the at least one Josephson junction along the qubit loop than the critical distance, if any, is ferromagnetically coupled to the qubit loop and each of the one or more couplers that is farther from the at least one Josephson junction along the qubit loop than the critical distance, if any, is anti-ferromagnetically coupled to the qubit loop.

In some implementations, for a predetermined target qubit inductance and a predetermined set of coupling strengths for the one or more couplers, the plurality of inductors are tunable to provide a total tunable inductance for each of the first, second, third, and fourth states which increases the qubit inductance to within a third threshold of the predetermined target qubit inductance and at least one of: increases and reduces the qubit capacitance to within a fourth threshold of the target capacitance.

In some implementations, the qubit comprises a second qubit loop, the at least one Josephson junction interrupting the second qubit loop; and at least one secondary inductor disposed along the second qubit loop. In some implementations, the qubit loop and second qubit loop partially overlap along a shared portion and a shared inductor of the plurality of inductors is disposed along the shared portion. In some implementations, the shared inductor comprises one of the one or more near inductors.

In some implementations, the at least one secondary inductor comprises one or more secondary near inductors, each secondary near inductor disposed along the second qubit loop less than a second critical distance from the at least one Josephson junction; and one or more secondary far inductors, each secondary far inductor disposed along the second qubit loop more than the second critical distance from the at least one Josephson junction. In some implementations, the plurality of inductors and the at least one secondary inductor collectively provide a collective tunable inductance range of at least twice a total coupler-induced inductance range.

Aspects of the present disclosure provide systems and methods for tuning an effective capacitance of a qubit in an analog computing system. The method is performed by a processor in communication with the analog computing system (e.g., by executing at least one of processor-executable instructions or data stored by at least one nontransitory processor-readable storage medium) and comprises determining a predicted capacitance for the qubit, determining a target capacitance for the qubit, determining a total capacitance change ΔC based on the target and predicted capacitances, and tuning a plurality of inductors. Each inductor is disposed at a corresponding distance from one or more Josephson junctions of the qubit along a qubit loop and is tuned to change the effective capacitance of the qubit based on the corresponding distances from the one or more Josephson junctions and the total capacitance change.

In some implementations, the one or more Josephson junctions have a critical distance such that adding a lumped inductance nearer than the critical distance to the one or more Josephson junctions along the qubit loop decreases a qubit capacitance at the one or more Josephson junctions and adding the lumped inductance further than the critical distance from the one or more Josephson junctions increases the qubit capacitance. In some implementations, tuning a plurality of inductors comprises tuning a first inductor of the plurality of inductors that is nearer to the one or more Josephson junctions than the critical distance along the qubit loop to decrease the qubit capacitance; and tuning a second inductor of the plurality of inductors that is farther from the one or more Josephson junctions along the qubit loop than the critical distance to increase the qubit capacitance.

In some implementations, tuning the plurality of inductors based on the corresponding distances from the one or more Josephson junctions comprises tuning the first and second inductors based on the first and second inductors' respective distances from a point disposed at the critical distance along the qubit loop from the one or more Josephson junctions.

In some implementations, the method comprises determining a predicted inductance for the qubit; determining a target inductance for the qubit; and determining a total inductance change ΔL based on the target and predicted inductances. In some implementations, tuning the plurality of inductors to change the effective capacitance of the qubit comprises tuning the plurality of inductors so that a sum of a corresponding plurality of tunable inductances of the plurality of inductors is within a threshold of a total inductance change ΔL and tuning the plurality of inductors so that the sum of the plurality of tunable inductances is distributed between the plurality of inductors based on the total capacitance change ΔC.

In some implementations, tuning the plurality of inductors so that the sum of the plurality of tunable inductances is distributed between the plurality of inductors based on the total capacitance change ΔC comprises tuning the tunable inductance of the first inductor of the plurality of inductors to reduce the effective qubit capacitance and increase an effective qubit inductance; and tuning the tunable inductance of the second inductor of the plurality of inductors to increase the effective qubit capacitance and increase the effective qubit inductance.

In some implementations, tuning the plurality of inductors so that the sum of the plurality of tunable inductances is distributed between the plurality of inductors based on the total capacitance change ΔC comprises selecting, from a plurality of candidate distributions of inductor tuning values, a selected distribution based on the total capacitance change ΔC and the total inductance change ΔL; and tuning the plurality of tunable inductors based on the inductor tuning values of the selected distribution.

In some implementations, each candidate distribution corresponds to a candidate capacitance change and selecting the selected distribution comprises selecting the selected distribution based on a difference between the candidate capacitance change and the total capacitance change ΔC.

In some implementations, tuning the plurality of tunable inductors based on the selected distribution comprises interpolating an interpolated inductor tuning value for each of the plurality of inductors based on the inductor tuning values of the selected distribution and the inductor tuning values of an additional one of the plurality of candidate distributions; and tuning the plurality of tunable inductors based on the interpolated inductor tuning values.

In some implementations, identifying the plurality of candidate distributions comprises identifying the plurality of candidate distributions in a lookup table based on at least one of the total capacitance change ΔC and the total inductance change ΔL; and wherein the additional one of the plurality of candidate distributions is proximate to the selected distribution in the lookup table.

In some implementations, identifying the plurality of candidate distributions of inductor tuning values comprises looking up a first set of inductor tuning values for one of the first and second inductors along a first axis of a lookup table and identifying for each of the first set of inductor tuning values a corresponding inductor tuning value for an additional one of the first and second inductors along a second axis of the lookup table such that the sum of the first and second inductor tuning values are within a threshold of the total inductance change ΔL, each inductor tuning value from the first set paired with the corresponding inductor tuning value for the additional one of the first and second inductors comprising a candidate distribution and corresponding to a predicted capacitance change.

In some implementations, selecting a selected distribution from the plurality of candidate distributions comprises selecting the candidate distribution with a corresponding predicted capacitance change nearest to the total capacitance change ΔC among the plurality of candidate distributions.

In some implementations, tuning the plurality of inductors so that the sum of the plurality of tunable inductances is distributed between the plurality of inductors based on the total capacitance change ΔC comprises looking up the total capacitance change ΔC along a first axis of a lookup table; looking up the total inductance change ΔL along a second axis of the lookup table; identifying a candidate distribution of inductor tuning values in the lookup table corresponding to the total capacitance change ΔC and total inductance change ΔL; and tuning the plurality of inductors based on the candidate distribution.

In some implementations, looking up at least one of the total capacitance change ΔC and total inductance change ΔL comprises determining an entry along at least one of the first and second axes of the lookup table approximating the at least one of the total capacitance change ΔC and total inductance change ΔL.

In some implementations, tuning a plurality of inductors comprises tuning a first inductor at a first distance from the one or more Josephson junctions along the qubit loop to reduce the effective qubit capacitance and increase an effective qubit inductance; and tuning a second inductor at a second distance from the one or more Josephson junctions along the qubit loop to increase the effective qubit capacitance and increase an effective qubit inductance, the second distance greater than the first distance.

In some implementations, determining a predicted capacitance for the qubit comprises determining a coupler-induced capacitance load based on one or more coupling strengths of one or more couplers coupled to the qubit.

In some implementations, tuning the plurality of inductors to change the effective capacitance of the qubit based on the total capacitance change comprises tuning the plurality of inductors to compensate for the coupler-induced capacitance load.

Aspects of the present disclosure provide a computational system comprising at least one processor in communication with an analog processor having at least one qubit and at least one nontransitory processor-readable storage medium that stores at least one of processor-executable instructions or data which, when executed by the at least one processor cause the at least one processor to perform actions comprising determining a predicted capacitance for the qubit, determining a target capacitance for the qubit, determining a total capacitance change ΔC based on the target and predicted capacitances, and causing the analog processor to tune a plurality of inductors, each inductor disposed at a corresponding distance from one or more Josephson junctions of the qubit along a qubit loop, to change the effective capacitance of the qubit based on the corresponding distances from the one or more Josephson junctions and the total capacitance change.

In some implementations, the actions may further comprise determining a predicted inductance for the qubit, determining a target inductance for the qubit, and determining a total inductance change ΔL based on the target and predicted inductances. Tuning the plurality of inductors to change the effective capacitance of the qubit may comprise tuning the plurality of inductors so that a sum of a corresponding plurality of tunable inductances of the plurality of inductors is within a threshold of the total inductance change ΔL and tuning the plurality of inductors so that the sum of the plurality of tunable inductances is distributed between the plurality of inductors based on the total capacitance change ΔC.

In some implementations, tuning the plurality of inductors based on the corresponding distances from the one or more Josephson junctions may comprise tuning a first inductor and a second inductor based on the respective distances of the first and second inductors from a point disposed at a critical distance along the qubit loop from the one or more Josephson junctions. Tuning the plurality of inductors so that the sum of the plurality of tunable inductances is distributed between the plurality of inductors based on the total capacitance change ΔC may comprise tuning the tunable inductance of the first inductor to reduce the effective qubit capacitance and increase an effective qubit inductance and tuning the tunable inductance of the second inductor to increase the effective qubit capacitance and increase the effective qubit inductance.

In some implementations, tuning the plurality of inductors so that the sum of the plurality of tunable inductances is distributed between the plurality of inductors based on the total capacitance change ΔC may comprises selecting, from a plurality of candidate distributions of inductor tuning values, a selected distribution based on the total capacitance change ΔC and the total inductance change ΔL and tuning the plurality of tunable inductors based on the inductor tuning values of the selected distribution. Selecting the selected distribution may comprise selecting the selected distribution based on a difference between a candidate capacitance change corresponding to the selected distribution and the total capacitance change ΔC.

In some implementations, tuning the plurality of tunable inductors based on the selected distribution may comprise interpolating an interpolated inductor tuning value for each of the plurality of inductors based on the inductor tuning values of the selected distribution and the inductor tuning values of an additional one of the plurality of candidate distributions and tuning the plurality of tunable inductors based on the interpolated inductor tuning values. Identifying the plurality of candidate distributions may comprise identifying the plurality of candidate distributions in a lookup table based on at least one of the total capacitance change ΔC and the total inductance change ΔL; and wherein the additional one of the plurality of candidate distributions is proximate to the selected distribution in the lookup table. Identifying the plurality of candidate distributions of inductor tuning values may comprise looking up a first set of inductor tuning values for one of the first and second inductors along a first axis of a lookup table and identifying for each of the first set of inductor tuning values a corresponding inductor tuning value for an additional one of the first and second inductors along a second axis of the lookup table such that the sum of the first and second inductor tuning values are within a threshold of the total inductance change ΔL, each inductor tuning value from the first set paired with the corresponding inductor tuning value for the additional one of the first and second inductors comprising a candidate distribution and corresponding to a predicted capacitance change.

In some implementations, selecting a selected distribution from the plurality of candidate distributions may comprise selecting the candidate distribution with a corresponding predicted capacitance change nearest to the total capacitance change ΔC among the plurality of candidate distributions. Tuning the plurality of inductors so that the sum of the plurality of tunable inductances is distributed between the plurality of inductors based on the total capacitance change ΔC may comprise looking up the total capacitance change ΔC along a first axis of a lookup table, looking up the total inductance change ΔL along a second axis of the lookup table, identifying a candidate distribution of inductor tuning values in the lookup table corresponding to the total capacitance change ΔC and total inductance change ΔL, and tuning the plurality of inductors based on the candidate distribution. Looking up at least one of the total capacitance change ΔC and total inductance change ΔL may comprise determining an entry along at least one of the first and second axes of the lookup table approximating the at least one of the total capacitance change ΔC and total inductance change ΔL.

In some implementations, tuning a plurality of inductors may comprise tuning a first inductor at a first distance from the one or more Josephson junctions along the qubit loop to reduce the effective qubit capacitance and increase an effective qubit inductance and tuning a second inductor at a second distance from the one or more Josephson junctions along the qubit loop to increase the effective qubit capacitance and increase an effective qubit inductance, the second distance greater than the first distance. Determining a predicted capacitance for the qubit may comprise determining a coupler-induced capacitance load based on one or more coupling strengths of one or more couplers coupled to the qubit. Tuning the plurality of inductors to change the effective capacitance of the qubit based on the total capacitance change may comprise tuning the plurality of inductors to compensate for the coupler-induced capacitance load.

Aspects of the present disclosure provide an analog computing system comprising a qubit, the qubit comprising a Josephson junction, a first qubit loop formed by a first superconducting current path, and a second qubit loop formed by a second superconducting current path, wherein the first qubit loop and the second qubit loop are electrically connected in parallel across the Josephson junction.

In some implementations, the analog computing system may further comprise a first flux bias line in communication with the first qubit loop and a second flux bias line in communication with the second qubit loop, the first flux bias line receiving signals independently from the second flux bias line. The second qubit loop may comprise a first portion in communication with the Josephson junction and a second portion spaced from the Josephson junction, the first portion and the second portion being separated by a crossing, wherein a current in the second qubit loop travels in a first rotational direction in the first portion and a second rotational direction that is opposite to the first rotational direction in the second portion.

In some implementations, the Josephson junction may comprise one of a compound Josephson junction or a compound-compound Josephson junction. The first qubit loop and the second qubit loop may partially overlap along a shared portion. The analog computing system may further comprise a coupler tunably coupled to one of the first qubit loop and the second qubit loop. The analog computing system may further comprise a second qubit coupled to the coupler. The first qubit loop and the second qubit loop may be symmetric about an axis of the Josephson junction, the axis of the Josephson junction intersecting a first connection between the first qubit loop and the second qubit loop and the Josephson junction and a second connection between the first qubit loop and the second qubit loop and the Josephson junction.

In some implementations, the analog computing system may further comprise one or more additional qubit loops electrically connected in parallel across the Josephson junction. The analog computing system may also further comprise a plurality of inductors disposed along each of the first qubit loop and the second qubit loop, each of the plurality of inductors being tunable to provide a corresponding tunable inductance.

In other aspects, the features described above may be combined in any reasonable combination as will be recognized by those skilled in the art.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements and may have been solely selected for ease of recognition in the drawings.

FIG. 1A is a schematic diagram of a prior art qubit.

FIG. 1B is a schematic diagram of a prior art qubit with an inductance tuner.

FIG. 2 is a schematic diagram of an example analog computing system comprising a qubit with inductors disposed at different distances along a qubit loop relative to one or more Josephson junctions of the qubit.

FIG. 3 is a schematic diagram of an example analog computing system comprising a qubit with serial DC-SQUID inductors disposed at different distances along a qubit loop relative to the one or more Josephson junctions of the qubit, with various further devices not shown in FIG. 2 also illustrated.

FIG. 4A is a schematic diagram of an example analog computing system comprising a qubit having two qubit loops, each loop substantially similar to the qubit loop of the exemplary qubit of FIG. 3.

FIG. 4B is a schematic diagram of an example analog computing system similar to that of FIG. 4A, except that two near inductors are replaced by one shared inductor.

FIG. 5 is a flowchart of a method for tuning an effective capacitance of an example qubit in an analog computing system, such as the analog computing system of FIG. 2.

FIG. 6 is a flowchart of a method for distributing inductance between near and far inductors, e.g., as part of the method of FIG. 5.

FIG. 7 is a schematic diagram showing an example hybrid computing system in which the technologies described herein may be implemented.

FIG. 8 is a schematic diagram of an example qubit having two loops.

FIG. 9A is a schematic diagram of an example qubit having two asymmetric loops.

FIG. 9B is a schematic diagram of an example qubit having three loops.

FIG. 10 is a schematic diagram of an example qubit having two loops and a twist.

FIG. 11 is a schematic diagram of an example qubit having two loops, a twist, and further devices.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

### L-Tuner

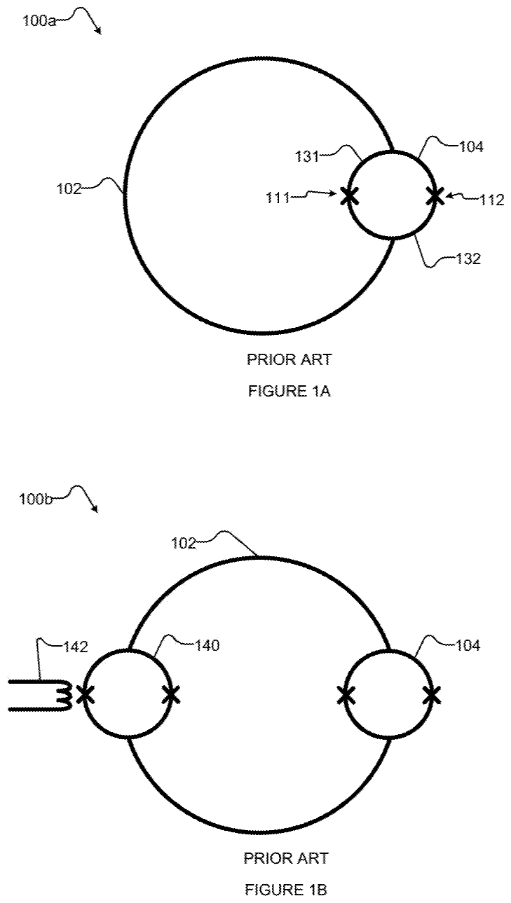

FIG. 1A is a schematic diagram of a superconducting flux qubit 100a. Qubit 100a comprises a qubit loop 102 (e.g., a loop of superconducting material) that is interrupted by one or more Josephson junctions. In the exemplary implementation of FIG. 1A, qubit loop 102 is interrupted by a compound Josephson junction 104 (also called a “CJJ”) comprising current paths 131, 132, each of which is interrupted by a respective Josephson junction 111, 112.

FIG. 1B is a schematic diagram of a superconducting flux qubit 100b. Qubit 100b comprises qubit loop 102 and compound Josephson junction 104, substantially similarly to qubit 100a. Qubit 100b further comprises an inductance tuner 140 (or “L-tuner”) which provides a tunable inductance to qubit 100b. Inductance tuner 140 may comprise, for example, a CJJ connected in series with compound Josephson junction 104 in qubit loop 102. As described, for example, in U.S. Pat. No. 9,152,923, inductance tuner 140 may be tuned using a programmable interface 142, such as by inductively and/or galvanically coupling control signals to inductance tuner 140 and thus tuning the Josephson inductance of compound Josephson junction 140 and, by extension, of qubit 100b.

Qubits 100a and 100b may be coupled to other devices inductively or otherwise. For example, in some implementations qubits 100a and 100b are inductively coupled to other qubits via inter-qubit couplers (not shown). Such couplings can affect the electromagnetic properties of qubits 100a, 100b. For example, the capacitance of qubit 100b may be a complex function of both coupler and L-tuner settings. Although in the past this effect has been small enough to ignore in practice, as quantum processors scale up experiments have shown that the effect increases. For example, in some implementations tuning both couplers and L-tuners can cause changes in qubit capacitance on the order of 10 fF, potentially causing errors in calibration, coupler-dependent desynchronization of qubit dynamics, and other difficult-to-address behaviour.

### Split L-Tuner

The effect of a lumped inductance on capacitance, such as that contributed by an L-tuner, varies with not only the scale of the inductance but also the position at which the lumped inductance is disposed along the qubit loop relative to one or more Josephson junctions that form part of the qubit. For example, an inductor coupled in series to (and positioned near to) the one or more Josephson junctions and possessing inductance Lₙₑₐᵣ can give rise to an effective qubit capacitance modeled as follows:

$${C}_{eff} = \frac{{L}_{Q}^{2}}{3 ( {L}_{Q} + {L}_{near} )} {C}_{Q}$$

where L_{Q}=L_{U}×L, C_{Q}=C_{U}×L, L is the length of the qubit loop, L_{U} is the intrinsic inductance of the qubit loop per unit length, and C_{U} is the intrinsic capacitance of the qubit loop per unit length. An inductor positioned farther away from the one or more Josephson junctions, e.g., at an opposing end of the qubit loop that forms part of the qubit, and possessing inductance L_{far} can give rise to an effective qubit capacitance C_{eff} measured at the one or more Josephson junctions which can be modeled as follows:

$${C}_{eff} = \frac{{L}_{Q}^{2} + 3 {L}_{Q} ( {L}_{Q} + {L}_{far} )}{3 {( {L}_{Q} + {L}_{far} )}^{2}} {C}_{Q} .$$

When Lₙₑₐᵣ=L_{far}=0, both models yield C_{eff}=C_{Q}/3, which is the expected capacitance of a shorted loop (the ⅓ factor arises from input impedance). However, in the case of Lₙₑₐᵣ>0, the resulting C_{eff} will be less than the expected C_{Q}/3. That is, increasing the inductance of the near inductor causes a reduction of effective qubit capacitance. The near inductor can thus be thought of as blocking a portion of the superconducting loop's intrinsic capacitance from being observed at the one or more Josephson junctions. The far inductor, however, can have an opposing effect; C_{eff} tends to increase as L_{far} increases.

Note that the capacitance-reducing behavior of the near inductor can be dominated by other dynamics if Lₙₑₐᵣ is sufficiently large, potentially resulting in an increase to the effective qubit capacitance C_{eff}. However, it has been determined through experiment that the near inductor's capacitance-reducing behavior can extend well beyond a typical programmable range for suitably positioned/scaled near inductors. (Herein, an inductor's “scale” refers to those structural features which dictate the amount of inductance that the inductor can contribute to qubit 201. For example, the scale of example inductor 206 may be at least partially determined by the size of its constituent Josephson junctions, with smaller Josephson junctions (e.g., with smaller area) generally corresponding to more inductance and thus greater scale. For some inductors, such as spiral inductors, larger area generally corresponds to more inductance and thus greater scale.)

Aspects of the present disclosure provide analog computing systems comprising a qubit which are advantageously provided with a plurality of tunable inductors, including inductors exhibiting the capacitance-reducing behavior described above with reference to Lₙₑₐᵣ (these are denominated herein and in the claims as “near inductors”) and inductors exhibiting the capacitance-increasing behavior described above with reference to L_{far} (these are denominated herein and in the claims as “far inductors”). Near and far inductors can be tuned independently to provide (or at least approximate) homogenous capacitance across a range of programmable states of the qubit. In some implementations, the inductors are tuned to provide (or at least approximate) both homogenous capacitance and homogenous inductance.

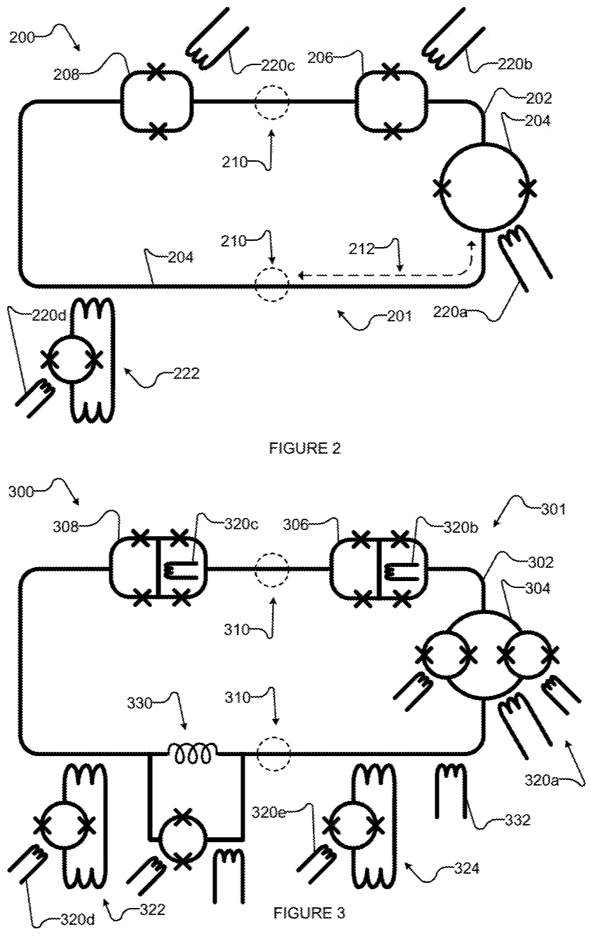

FIG. 2 shows an example analog computing system 200 comprising a qubit 201 having a qubit loop 202 and one or more Josephson junctions 204 (in the depicted exemplary implementation, one or more Josephson junctions 204 comprise a CJJ). A near inductor 206 interrupts qubit loop 202 and is tunable to provide a corresponding tunable inductance Lₙₑₐᵣ. A far inductor 208 interrupts qubit loop 202 and is tunable to provide a corresponding tunable inductance L_{far}. (In some implementations, one, some, or all of inductors 206, 208 are inductively coupled to qubit loop 202.) In the exemplary depicted implementation of FIG. 2, analog computing system 200 further comprises a coupler 222 which is communicatively coupleable to qubit loop 202. Various devices of analog computing system 200 may be programmed via one or more programmable interfaces; in the exemplary depicted implementation, one or more Josephson junctions 204, near inductor 206, far inductor 208, and coupler 222 are programmable via programmable interfaces 220a, 220b, 220c, 220d, respectively. Although the exemplary implementation of FIG. 2 shows one near inductor 206 and one far inductor 208, it will be appreciated in view of the disclosure herein presented that pluralities of near and far inductors may be provided without straying from the scope of the present disclosure.

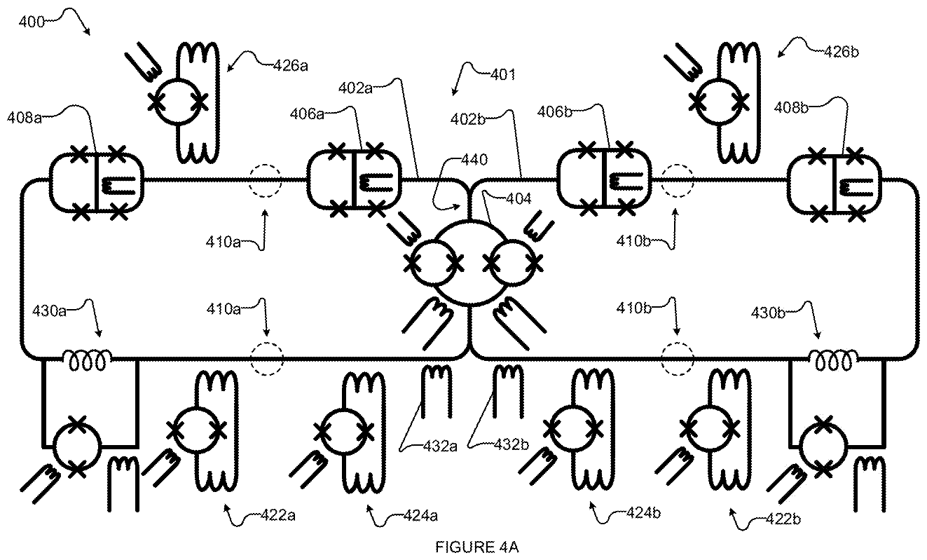

Inductors 206, 208 may comprise any tunable inductor. In some implementations, at least one of inductors 206, 208 comprises an L-tuner, e.g., as described in U.S. Pat. No. 8,536,566, and may for example comprise one or more Josephson junctions, e.g., arranged into one or more DC-SQUIDs. In the exemplary depicted implementation, each inductor 206, 208 comprises a DC-SQUID having two Josephson junctions connected in parallel and tunable via respective programming interfaces 220b, 220c. Inductors 206, 208 may alternatively or additionally comprise other sources of lumped inductance, such as a quantum flux parametron or a mutual inductance inductively coupled to the qubit loop. Inductors 206, 208 may have the same or different structure; for example, inductor 206 may comprise a single DC-SQUID and inductor 208 may comprise two DC-SQUIDs in series. (Inductor 308 of FIG. 3 is an example of the latter.)

Inductors 206, 208 are tunable (e.g., via respective programmable interfaces 220b, 220c) to provide respective inductances Lₙₑₐᵣ and L_{far} within a tunable inductance range. For example, if inductor 206 is tunable to provide Lₙₑₐᵣ as low as 0 fF and as large as 10 fF, the tunable inductance range of inductor 206 is said to be 10 fF. These figures exclude any parasitic/baseline inductance, which is not tunable; for instance, continuing the previous example, if inductor 206 also provides 2 fF of parasitic inductance, and thus provides between 2 fF and 12 fF of inductance depending on its tuning, the tunable inductance range of inductor 206 is still said to be 10 fF. Inductors 206, 208 may have the same or different tunable inductance ranges.

Near inductor 206 and far inductor 208 are distinguished by their positions relative to one or more Josephson junctions 204 of qubit 201. As near inductor 206 is positioned nearer along qubit loop 202 to one or more Josephson junctions 204, near inductor 206 will tend to reduce capacitance to a greater degree (for a given increase in Lₙₑₐᵣ). As far inductor 208 is positioned farther along qubit loop 202 from one or more Josephson junctions 204, far inductor 208 will tend to increase capacitance to a greater degree (for a given increase in L_{far}). An inductor nearer to one or more Josephson junctions than a critical distance 212 will behave generally as near inductor 206 (i.e., reducing capacitance) and an inductor farther from one or more Josephson junctions than critical distance 212 will behave generally as far inductor 208.

There can thus be inferred critical points 210 along qubit loop 202 positioned at the critical distance 212 from one or more Josephson junctions 204. Critical points 210 divide the near- and far-inductor regimes, such that inductors between one or more Josephson junctions 204 and a critical point behave as near inductors and inductors between critical points 210 along a portion of qubit loop 202 which does not contain (e.g., which opposes) one or more Josephson junctions 204 behave as far inductors. Inductors nearer to the critical point will tend to have a less pronounced effect on qubit capacitance (for a given change in inductance) than inductors farther from the critical point. This scaling of capacitance-increasing or capacitance-reducing behavior is not necessarily symmetric between near and far inductors (e.g., near inductors may tend to reduce qubit capacitance by a smaller amount than far inductors even if both have the same inductance and distance from a critical point 210). Although in at least some implementations it is not necessary to expressly identify the location of critical points 210, in some implementations inductors 206, 208 (and/or other devices of system 200) are placed relative to critical points 210 to determine the relationship between their inductance and their impact on the qubit capacitance.

Inductors 206, 208 can be tuned to compensate for capacitance and/or inductance contributed to qubit 201 (so-called capacitive and/or inductive loading) by various devices. For example, coupler 222 may induce capacitive and inductive loading in qubit 201, and inductors 206, 208 can be tuned to compensate for one or both such loadings. In some implementations, inductors 206, 208 are positioned and operable to provide tunable inductance ranges such that inductors 206, 208 are capable of homogenizing qubit capacitance and/or inductance across a plurality of states of qubit 201.

For example, analog computing system 200 may be operable to put qubit 201 in a maximum-inductance state by setting all couplers 222 to ferromagnetically couple to qubit loop 202. For instance, if all couplers 222 are programmable to provide a range of coupling strengths expressed in the range [−1,1], where negative values are ferromagnetic and positive values are antiferromagnetic, the maximum-inductance state may comprise a state where all couplers 222 are programmed to provide a coupling strength of −1. Continuing the foregoing example, analog computing system 200 may be able to put qubit 201 in a minimum-inductance state by setting all couplers 222 to antiferromagnetically couple to qubit loop 202 (e.g. corresponding to a coupling strength of 1).

In some implementations, the difference between the qubit inductance at the maximum-inductance state and the qubit inductance at the minimum-inductance state is no greater than the sum of the ranges of tunable inductance of inductors 206, 208. That is, tunable inductors 206, 208 are collectively tunable to provide sufficient tunable inductance range homogenize the minimum- and maximum-inductance states' qubit inductance. For example, consider the following states for an exemplary implementation of qubit 201:

| State | Device Settings | Qubit Inductance |
|---|---|---|
| Minimum | All couplers set to antiferromagnetic | 100 pH |
| inductance | coupling | |
| Maximum | All couplers set to ferromagnetic | 200 pH |
| inductance | coupling | |

The difference in qubit inductance between the minimum- and maximum-inductance states is 100 pH, called the target inductance range herein. In some implementations, inductors 206, 208 provide a collective tunable inductance range of at least 100 pH. For example, inductor 206 could provide 40 pH of tunable inductance range, and inductor 208 could provide 60 pH of tunable inductance range. In some implementations, inductors 206, 208 provide a collective tunable inductance range that is greater than the target inductance range (e.g., more than 100 pH of the foregoing example), for instance to provide an allowance for variations in fabrication.

Inductors 206, 208 may also, or alternatively, be tunable to homogenize capacitance between maximum-capacitance and minimum-capacitance states of qubit 201. For example, analog computing system 200 may be operable to put qubit 201 in a maximum-capacitance state by setting all couplers 222 within critical distance 212 of one of more Josephson junctions 204 to antiferromagnetically couple to qubit loop 202 (in which case the couplers 222 within critical distance 212 reduce inductance and increase capacitance, as they are in the near-inductor region of qubit loop 202) and setting all couplers 222 farther than critical distance 212 from one or more Josephson junctions 204 to ferromagnetically couple to qubit loop 202 (in which case the couplers 222 farther than critical distance 212 increase both inductance and capacitance, as they are in the far-inductor region of qubit loop 202). For example, consider the following states for an exemplary implementation of qubit 201:

| | | Qubit |
|---|---|---|
| | | Capaci- |
| State | Device Settings | tance |
| Minimum | Couplers within the critical distance of one | 100 fF |
| capacitance | or more Josephson junctions 204 set to | |
| | antiferromagnetic coupling | |
| Maximum | Couplers beyond the critical distance from | 200 fF |
| capacitance | one or more Josephson junctions 204 set to | |
| | ferromagnetic coupling | |

In some implementations, inductors 206, 208 are tunable to homogenize the qubit capacitance of both the maximum-capacitance and minimum-capacitance states, for example by increasing or reducing the qubit capacitance to a target capacitance, as appropriate. For example, inductors 206, 208 may be tunable to increase the qubit capacitance of qubit 201 from the qubit capacitance of the minimum-capacitance state to within a threshold of a target capacitance and to decrease the qubit capacitance from the qubit capacitance of the maximum-capacitance state to within a threshold of the target capacitance. (These two thresholds may be the same as one another or different from one another.)

For instance, if the target capacitance for analog computing system 200 is 150 fF, the near inductors (e.g., inductor 206) may be tunable to reduce capacitance by at least 50 fF (to address the maximum-capacitance case) and the far inductors may be tunable to increase capacitance by at least 50 fF (to address the minimum-capacitance case).

Although the foregoing discussion refers to states induced by couplers, which are in many implementations the principal sources of varying inductive and capacitive load, minimum—and maximum-inductance and—capacitance states may be determined based on the programmable states of any devices which contribute inductive and/or capacitive load to qubit 201. Such devices include, for example, quantum flux parametrons and mutual inductances coupled to qubit 201 (e.g., a flux bias device).

In some implementations, inductors 206, 208 are tunable to homogenize both qubit inductance and qubit capacitance across each of four extreme states: minimum inductance, maximum inductance, minimum capacitance, and maximum capacitance. The relationship between inductance and capacitance is not always linear, so conforming to these constraints for both inductance and capacitance can be expected to materially affect the parameters of inductors 206, 208 in most circumstances. However, since the four extreme states define extrema in the state space of qubit 201, it is expected that in at least some implementations inductors 206, 208 which are tunable to homogenize all four extreme states across both inductance and capacitance will be tunable to homogenize all programmable states of system 200 (or, more particularly, across any programmable states of the devices varied between the four extreme states). For example, consider the following states for an exemplary implementation of qubit 201:

| | | Qubit | Qubit |
|---|---|---|---|
| | | Induc- | Capaci- |
| State | Device Settings | tance | tance |
| Minimum | All devices set to decrease effective | 100 pH | 120 fF |
| inductance | qubit inductance | | |
| Maximum | All devices set to increase effective | 200 pH | 180 fF |
| inductance | qubit inductance | | |
| Minimum | All devices within the critical distance | 120 pH | 100 fF |
| capacitance | of one or more Josephson junctions | | |
| | 204 set to decrease effective qubit | | |
| | inductance | | |
| Maximum | All devices within the critical distance | 180 pH | 200 fF |
| capacitance | of one or more Josephson junctions | | |
| | 204 set to increase effective qubit | | |
| | inductance | | |

In such implementations, near and far inductors 206, 208 must be positioned and provided with tunable inductance ranges which allow for each of the four extreme states to have (approximately, within a threshold) the same inductance and capacitance once the inductors are suitably tuned.

For example, suppose an analog computing system has a target inductance of 220 pH and a target capacitance of 160 fF. Then, for an exemplary implementation of qubit 401 with a given positioning of inductors 206, 208, inductance and capacitance might be homogenized across various programmed states of analog system 200 (sometimes referred to as “scenarios” herein) as follows:

| | Qubit | Qubit | | |
|---|---|---|---|---|
| State | Inductance | Capacitance | Lₙₑₐᵣ | L_{far} |
| Minimum inductance | 220 pH | 160 fF | 40 pH | 80 pH |
| Maximum inductance | 220 pH | 160 fF | 0 pH | 20 pH |
| Minimum capacitance | 220 pH | 160 fF | 80 pH | 20 pH |
| Maximum capacitance | 220 pH | 160 fF | 40 pH | 0 pH |

Here, the qubit capacitance column excludes the capacitance of one of more Josephson junctions 204, Lₙₑₐᵣ is the tuned inductance of near inductor 206, and L_{far} is the tuned inductance of far inductor 208. This example scenario implies that each of Lₙₑₐᵣ and L_{far} require 80 pH of tunable inductance range.

In some implementations, near and far inductors 206, 208 provide a total tunable inductance range (i.e., the sum of their tunable inductance ranges) which is substantially the same as the total inductance range of a single L-tuner, e.g. as described in U.S. Pat. No. 8,536,566. For instance, if 50 pH of tunable inductance range would be required for a single L-tuner, the near and far inductors 206, 208 may collectively provide 50 pH of tunable inductance range. That tunable inductance range may be distributed between inductors 206, 208 in any appropriate way (e.g., 20 pH of tunable inductance range for inductor 206 and 30 pH of tunable inductance range for inductor 208). The choices of such distribution of tunable inductance range and the positions of inductors 206, 208 are intertwined—for instance, an inductor with a smaller tunable inductance range may need to be positioned farther from critical point 210 to provide adequate capacitance reduction/increase.

A variety of arrangements of inductors 206, 208 may satisfy such conditions. Different arrangements may be compared (e.g., by simulation), and the selection of a particular arrangement may be affected by factors such as locations available on the processor for device placement, proximity to other devices, fabrication tolerances, and/or other factors. Simulations may be assisted by adding a constraint that, for each scenario, there is some fixed total inductance value Lₜₒₜₐₗ such that Lₜₒₜₐₗ=Lₙₑₐᵣ+L_{far}. (Lₜₒₜₐₗ may vary between scenarios.) Lₜₒₜₐₗ may be determined based on a single L-tuner implementation, as described above; the scope of the simulation may thus be reduced to exploring different combinations of tunable inductance range distribution between inductors 206, 208 and placements of inductors 206, 208.

In some implementations, system 200 comprises more than one near inductor 206 and/or more than one far inductor 208 (e.g., by providing secondary near and/or far inductors). The collective near inductors 206 may then collectively provide a tunable inductance Lₙₑₐᵣ and a corresponding tunable inductance range; the various placements of the near inductors 206 will then determine the collective effect of near inductors 206 on qubit capacitance. Similarly, the collective far inductors 208 may then collectively provide a tunable inductance L_{far} and a corresponding tunable inductance range; the various placements of the far inductors 208 will then determine the collective effect of far inductors 208 on qubit capacitance.

FIG. 2 is simplified for convenience of illustration.

FIG. 3 shows a more complex example analog computing system 300 comprising a qubit 301 having a qubit loop 302 and one or more Josephson junctions 304. In the depicted exemplary implementation, one or more Josephson junctions 304 comprise a compound-compound Josephson junction, or CCJJ, which comprises two compound Josephson junctions. Near inductor 306 and far inductor 308 each comprise two DC-SQUIDs connected in series and provide tunable inductances Lₙₑₐᵣ and L_{far}, respectively. In at least some implementations, the compound features of one or more Josephson junctions 304 and inductors 306, 308 can allow for more precise tuning within a programmable range relative to the simpler devices of FIG. 2.

System 300 also provides a plurality of couplers coupleable to qubit 301, including far coupler 322 and near coupler 324. Far coupler 322 is disposed more than the critical distance from one or more Josephson junctions 304 along qubit loop 302 (i.e., on the far side of critical point 310), and near coupler 324 is disposed less than the critical distance from one or more Josephson junctions 304 (i.e., on the near side of critical point 310). Couplers 322, 324 will thus tend to have different effects on qubit capacitance as their inductive load on qubit 301 changes.

In implementations where inductors 306, 308 are positioned and of suitable scale to compensate for such inductive and/or capacitive load, the position and/or scale of one or both of inductors 306, 308 may be affected by the arrangement of couplers 322, 324. For example, in some implementations inductors 306, 308 may be positioned and/or scaled to compensate for capacitance in a maximum-capacitance scenario where near coupler 324 is antiferromagnetically coupled to qubit 301 and far coupler 322 is ferromagnetically coupled to qubit 301 (e.g., as described above), and vice-versa for the minimum-capacitance scenario.

One or more Josephson junctions 304, inductors 306, 308, and couplers 322, 324 are programmable via programmable interfaces 320a, 320b, 320c, 320d, 320e, respectively. System 300 further provides exemplary other devices such as a quantum flux parametron 330 interrupting qubit loop 302 and a programmable flux bias 332 coupleable to qubit 301. Such other devices may be used to interact with qubit 301 (e.g., to read out its state and/or to program it with the relevant parameters of a problem Hamiltonian) and may contribute to inductive and/or capacitive loading of qubit 301. In some implementations, inductors 306, 308 are positioned and/or scaled to compensate for inductive and/or capacitive loading contributed by such other devices (e.g., so as to compensate for the load contributed by operating such other devices to increase or decrease inductive or capacitive load, as appropriate, in the various scenarios described elsewhere herein).

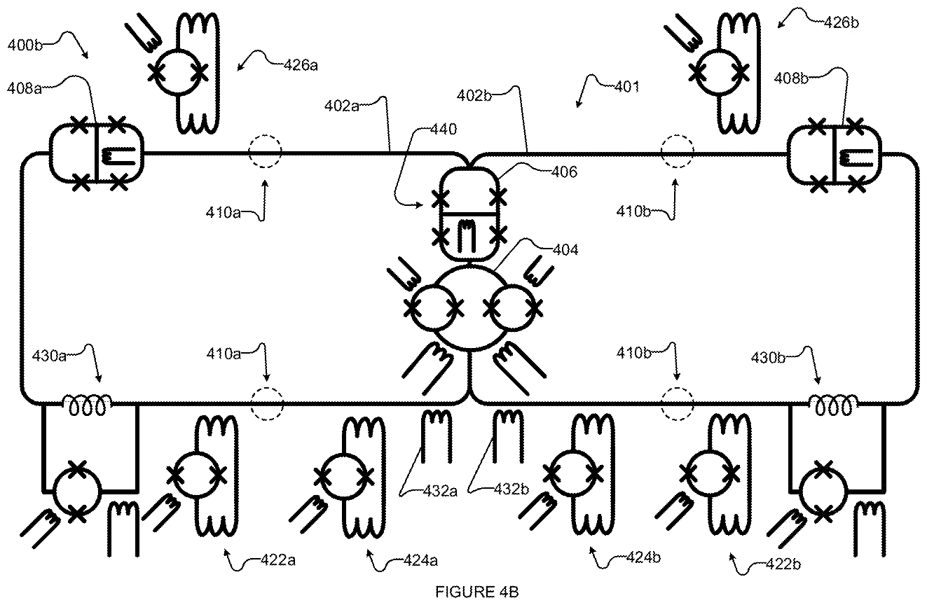

The systems disclosed herein are not limited to single-qubit-loop implementations. FIG. 4A shows an example analog computing system 400 comprising a qubit 401 having a plurality of qubit loops 402a, 402b interrupted by one or more Josephson junctions 404 shared between qubit loops 402a, 402b. (Qubit loops 402a, 402b may partially overlap along a shared portion 440, e.g., as shown in FIG. 4A.) In at least the depicted exemplary implementation, each qubit loop 402a, 402b is coupleable to and/or comprises devices substantially similar to those of systems 200, 300.

For example, in the depicted embodiment qubit loop 402a is interrupted by near inductor 406a and far inductor 408a (disposed on opposing sides of critical point 410a) and is communicatively coupleable to a plurality of couplers 422a, 424a, 426a. Qubit loop 402a may further be coupleable to and/or comprises other devices, such as quantum flux parametron 430a and/or flux bias 432a. Qubit loop 402b may be coupleable to and/or comprise similar or different devices; in the depicted exemplary implementation, qubit loop 402b is substantially similar to qubit loop 402a and is interrupted by near inductor 406b and far inductor 408b (disposed on opposing sides of critical point 410b) and is coupleable to a plurality of couplers 422b, 424b, 426b. Qubit loop 402b may further be coupleable to and/or comprises other devices, such as quantum flux parametron 430b and/or flux bias 432b.

In some implementations, qubit loops 402a, 402b have critical points 410a, 410b which are disposed at different critical distances from one or more Josephson junctions 404—e.g., where qubit loops 402a, 402b are not identical (e.g., where they are composed of different materials, have asymmetric layout, and/or are coupleable asymmetrically to other devices of system 400a). Critical point 410b may thus be said to be disposed by a second critical distance from the one or more Josephson junctions along qubit loop 402b, which may be the same as or different than the critical distance of critical points 410a.

In some implementations, each qubit loop 402a, 402b comprises at least one near inductor 406a and at least one far inductor 408a, thereby allowing for inductive and/or capacitive load on each loop to be compensated for independently. In some implementations, qubit loops 402a, 402b share at least one near inductor 406a and/or far inductor 408a. For example, as depicted in exemplary system 400b of FIG. 4B, a shared near inductor 406 may be positioned along shared portion 440. In some implementations, shared near inductor 406 provides greater tunable inductance range than either near inductor 406a, 406b of otherwise-similar system 400 in order to compensate for inductance across both qubit loops 402a, 402b. A potential advantage of such an arrangement is space-saving; in addition to reducing the minimum number of inductors required (from one on each wing to one per qubit), shared inductor 406 can itself be physically smaller (e.g., by providing a DC-SQUID with smaller Josephson junctions, as smaller Josephson junctions generally provide greater inductance than larger ones). This difference in size is not depicted to maintain legibility of FIG. 4B.

In some implementations the collective tunable range of near and far inductors 406a, 406b, 408a, 408b of a qubit 401 with multiple loops 402a, 402b is larger than the amount indicated by the difference in inductance between the maximum-inductance and minimum-inductance states by a tolerance amount (e.g., 20 pH). This tolerance amount may be sufficiently large to allow the near and far inductors 406a, 406b, 408a, 408b to be tuned to compensate for variations between wings arising from fabrication defects, design variances, and/or other asymmetries. This tolerance value may be further increased to account for variances between qubits, e.g. as described elsewhere herein.

### Tuning Split L-Tuners

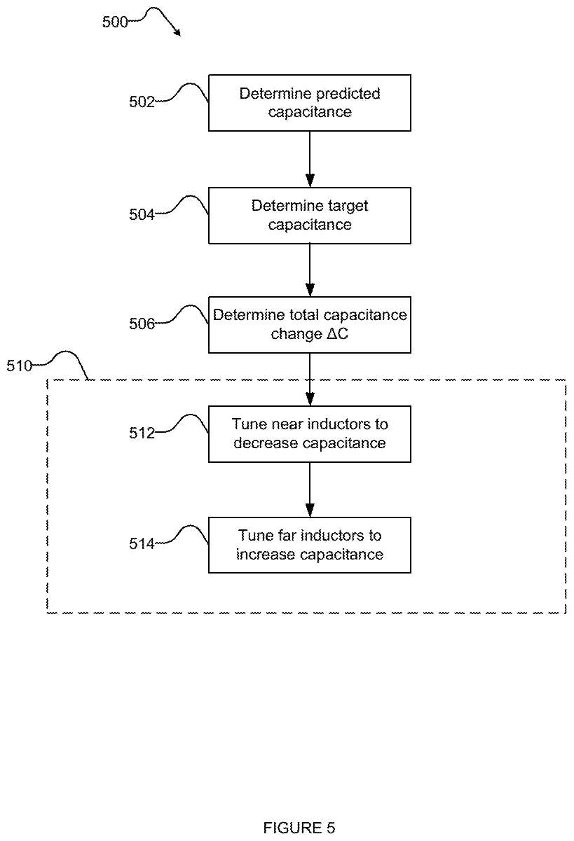

FIG. 5 is a flowchart of a method 500 for tuning an effective capacitance of a qubit in an analog computing system, such as qubit 201, 301, or 401 of system 200, 300, or 400, respectively. The method is performed by one or more processors (e.g., classical processors) in communication with the analog computing system.

At 502, the one or more processors determine a predicted capacitance for the qubit, denoted C_{predicted}, based on a problem to be executed by the analog computing system. For example, if a given problem is transformed into a Hamiltonian for encoding onto the analog computing system (a process sometimes called “embedding”), the one or more processors may determine C_{predicted} for the qubit by applying the portions of the Hamiltonian relating to that qubit (e.g., the parameters corresponding to coupling strengths for couplers coupleable to the qubit) to a physical model of the qubit. For instance, the one or more processors may determine, for each coupler, an associated inductive load for the qubit based on a respective coupling strength of each coupler, and may further determine an associated capacitive load for the qubit based on a respective inductive load of each coupler and a respective distance of each coupler from the one or more Josephson junctions of the qubit along the qubit loop, e.g., based on the models for C_{eff} described above. The one or more processors may combine these capacitive loads (e.g., by summing the capacitive loads, and/or by a weighted or non-linear combination) and, based on the combined capacitive loads and any other suitable factors (such as capacitive loads of other devices, a baseline capacitance of the qubit, and the programmed state of the one or more Josephson junctions) determine a predicted capacitance C_{predicted} of the qubit.

At 504, the one or more processors determine a target capacitance for the qubit, denoted C_{target}. Method 500 aims to tune the effective capacitance of the qubit to be within a threshold of target capacitance C_{target}. Target capacitance C_{target} may be predetermined (e.g., the target capacitance C_{target} may be a fixed value for the qubit determined at design-time), in which case the determination by the processor may comprise retrieving a value of the target capacitance C_{target} from a data store. A predetermined target capacitance C_{target} may be determined, for example, by experimental methods, such as by using magnetic resonance tunneling, qubit spectroscopy, and/or other techniques to identify qubit capacitance. For instance, in a quantum-annealing system, this may involve observing the behavior of a qubit (and/or a larger system, such as system 200, 300, 400) at the quantum critical point—that is, at the energy scale where disordering and problem Hamiltonians have equal energy—to ensure it exceeds some baseline noise threshold given a certain capacitance.

In some implementations, target capacitance C_{target} is determined dynamically by the processor, e.g., after receiving a given problem for execution by the quantum processor. For instance, target capacitance may be determined by determining predicted capacitances C_{predicted} for each of a plurality of qubits of the analog computing system for a given problem and determining a target capacitance C_{target} based on those predicated capacitances C_{predicted}, such as by taking an average of the target capacitances, and/or by determining a value for C_{target} which minimizes an objective function (e.g., a sum of L1 or L2 norms between each qubit's C_{predicted} and C_{target}). Such determination may be subject to one or more constraints; for example, the choice of C_{target} may be constrained so that the analog computing system is operable to increase or decrease (as appropriate) the effective capacitance C_{eff} of each qubit of the plurality from each qubit's predicted capacitance C_{predicted} to within a threshold of the target capacitance C_{target}.

At 506, the one or more processors determine a total capacitance change for the qubit, denoted ΔC, based on the predicted capacitance C_{predicted} and target capacitance C_{target}. In at least some implementations, the total capacitance change ΔC is the difference between C_{target} and C_{predicted}.

At 510, the one or more processors tune a plurality of inductors of the analog computing system to change the effective capacitance of the qubit based on the distance of each inductor from the one or more Josephson junctions of the qubit along the qubit loop and based on the total capacitance change ΔC. For instance, the one or more processors may tune the plurality of inductors to increase or decrease (as appropriate) the effective capacitance of the qubit, C_{eff}, by an amount which is within a threshold of ΔC. Such tuning may comprise, for example, transmitting a representation of the problem to the analog computing system for execution (and thus causing the analog computing system to execute the representation of the problem) which includes parameters which cause the analog computing system to program the plurality of inductors to provide the tunable inductances determined in the course of performing method 500. In some implementations, the one or more processors tune the inductors to compensate for a coupler-induced capacitive load (e.g., predicted as described above with reference to act 502).

In at least some implementations, the tuning of act 510 comprises tuning a near inductor which is nearer to the one or more Josephson junctions than the critical distance along the qubit loop to decrease the qubit capacitance (at act 512) and tuning a far inductor which is farther from the one or more Josephson junctions than the critical distance along the qubit loop to increase the qubit capacitance (at act 514).

The near and far inductors may be tuned based on their respective distances from the one or more Josephson junctions—for example, by tuning the near and far inductors based on their distances from a critical point (such as the nearest critical point). As noted elsewhere herein, the capacitive load of an inductor per unit of inductance generally varies with the position of the inductor along the qubit loop. Thus, determining the inductance required to achieve a particular change in the effective qubit capacitance C_{eff} may comprise, for example, looking up a value from a datastore (such as a lookup table) which stores values of capacitive change for corresponding changes in inductance for inductors of a certain distance from the one or more Josephson junctions (such values may be predetermined, e.g., experimentally), applying a model of qubit capacitance to an inductor based on the distance of the inductor from the one or more Josephson junctions (e.g., by using a model which explicitly includes such distance as a parameter, and/or by selecting a model based on that distance, such as one of the models for C_{eff} given above), and/or other approaches.

The tuning of act 510 may be as simple as tuning one of the near or far inductors to achieve (or at least approximate) the desired total capacitance change ΔC, for example by increasing the inductance of a far inductor to increase capacitance by ΔC (or at least to within a threshold of ΔC) or by increasing the inductance of a near inductor to decrease capacitance by ΔC. However, in at least some circumstances, such tuning can cause the effective inductance of the qubit to become less homogeneous across different programmed states of the qubit.

Such inhomogeneity can be undesirable in at least some applications. In at least some implementations, method 500 further comprises determining predicted and target inductances for the qubit, determining a total inductance change ΔL based on the predicted and target inductances, and tuning the plurality of inductors to increase the collective inductance of the inductors (that is, the sum of their inductances) by an amount which is within a threshold of ΔL.

Note that the change in qubit inductance is not necessarily the same as the value of ΔL, since the inductance contributed by an inductor to effective qubit capacitance may be less than the inductance contributed locally by the inductor. For example, the case of qubit 401 of FIG. 4A the effective qubit inductance can in some situations increase by roughly a quarter-unit for every unit of tunable inductance contributed by an inductor 406a, 406b, 408a, 408b (e.g., where the inductances of qubit loops 402a, 402b are roughly equal) due to the parallel arrangement of qubit loops 402a, 402b. Accordingly, in some embodiments, determining the total inductance change ΔL comprises determining a total inductance change for the inductors to achieve (or at least approximate) a total inductance change for the qubit, where the total inductance change is determinable (e.g., based on a difference between the target and predicted inductances).

In at least some implementations, the total inductance change is distributed between inductors based not only on ΔL but also based on ΔC. For example, method 500 may homogenize (to within a threshold) both ΔL and ΔC across various programmed states of the analog computing system (such as the states described elsewhere herein). A given total inductance change ΔL can be distributed between inductors in various ways, but in most circumstances most such distributions will not achieve (or at least approximate) a specific desired change in qubit capacitance.

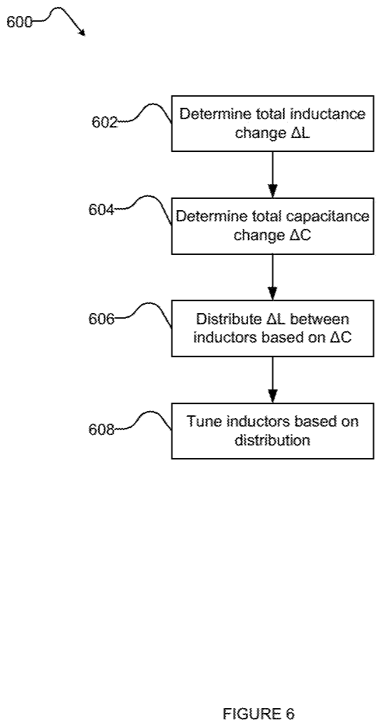

FIG. 6 is a flowchart of a method 600 for distributing inductance between near and far inductors. The method is performed by one or more processors (e.g., classical processors) in communication with the analog computing system and may be performed as part of method 500. At 602, the one or more processors determine a total inductance change ΔL (e.g., based on target and predicted inductances, as described above) and at 604, the one or more processors determine a total capacitance change ΔC (e.g., based on target and predicted capacitances, as described above with reference to act 506 of method 500).

At 606, the one or more processors determine a distribution of the total inductance change ΔL between the inductors of the analog computing system so that the corresponding tunable inductances of the inductors are collectively within a threshold of the total inductance change ΔL (e.g., so that the sum of those tunable inductances sum to within a threshold of the total inductance change ΔL) based on the total capacitance change ΔC. In some implementations, act 606 comprises identifying a plurality of candidate distributions of inductor tuning values. Each candidate distribution comprises values of tunable inductance for each of the inductors and thus corresponds to a capacitance change arising from (and/or predicted to arise from) tuning the inductors to provide those values of tunable inductance. A distribution may then be selected from the plurality of candidates, e.g., by selecting the candidate with a (predicted) capacitance change which is nearest the total capacitance change ΔC.

The plurality of candidate distributions may be determined by, for example, looking up a value in a lookup table which associates values of ΔL to values of ΔC. In some implementations, the lookup table has ΔL and ΔC values as axes and each (ΔL, ΔC) coordinate in the table maps to a candidate distribution which provides (or is predicted to provide) the corresponding ΔL and ΔC values being looked up (at least to within a threshold). For example, in an exemplary two-inductor system 200 such as that illustrated in FIG. 2, if a total inductance change ΔL=100.1 pH was determined at act 602 and a total capacitance change ΔC=59.9 fF was determined at act 604, act 606 may comprise looking up the coordinate (100 pH, 60 fF) in the lookup table and identifying a candidate distribution Lₙₑₐᵣ=80 pH, L_{far}=20 pH. (The foregoing example assumes that a coordinate that more precisely approximates the lookup value is not represented by the table.)

In some implementations, the lookup table has values of tunable inductance as axes (e.g., Lₙₑₐᵣ and L_{far}) and maps each coordinate (e.g. (Lₙₑₐᵣ, L_{far}) coordinate) to a candidate ΔC value. (In some implementations, ΔL is also mapped to by the table; in other implementations, ΔL is omitted by the table, in which case ΔL may be inferred by combining the coordinate values, e.g., by calculating ΔL=Lₙₑₐᵣ+L_{far}). A plurality of candidate distributions may be identified in the table, e.g., by identifying all coordinates which correspond (at least within a threshold) to the total inductance change ΔL. For instance, in an exemplary two-axis table having Lₙₑₐᵣ and L_{far} as axes, a diagonal may be identified (e.g., defined by, for each value of Lₙₑₐᵣ, the (Lₙₑₐᵣ, L_{far}) coordinate where Lₙₑₐᵣ=ΔL−L_{far}, if such a value exists, at least approximately) and the value along that diagonal with a corresponding candidate ΔC value which is closest to the total conductance change ΔC may be selected. Such lookup tables may comprise more than two dimensions (e.g., to explicitly represent more than two inductors along its axes). However, even where more than two tunable inductors are provided, the lookup table may provide fewer axes; for instance, the lookup table may provide Lₙₑₐᵣ and L_{far} as axes, allowing the one or more processors to distribute inductance between the near and far inductors. Sub-distributions among the near inductors (based on Lₙₑₐᵣ) and the far inductors (based on L_{far}) may subsequently be determined by reference to other lookup tables, by applying models, or via other suitable approaches.

In some implementations, act 606 comprises interpolating inductor tuning values for the inductors of the analog computing system. For example, the inductor tuning values for a coordinate (e.g., (ΔL, ΔC), (Lₙₑₐᵣ, L_{far}), and/or some other coordinate) may be interpolated based on the selected distribution and based on an additional candidate distribution, such as a candidate distribution which is proximate (e.g., adjacent) to the selected distribution in the lookup table. As used herein, “proximate” refers to a distribution that is within a small threshold (e.g., one integer value, +1% of each coordinate value) of variation around the selected distribution. This threshold will define an area around the coordinates of the selected distribution that is considered to be “proximate”. For instance, returning to the foregoing example where a total inductance change ΔL=100.1 pH was determined at act 602 and a total capacitance change ΔC=59.9 fF was determined at act 604, act 606 may comprise selecting the candidate distribution at the distribution (100 pH, 60 fF), e.g., as described above, and interpolating a value for the coordinate (100.1 pH, 59.9 fF) by interpolating the inductor tuning values for (100 pH, 60 fF) with the inductor tuning values for an additional candidate distribution having coordinates (101 pH, 59 fF). The interpolation may comprise taking a weighted average of the selected distribution and that other candidate distribution, e.g., weighted based on each distribution's distance (e.g., Cartesian distance) from the coordinate (100.1 pH, 59.9 fF), where nearer distributions receive greater weight. In this example, the “proximate” distribution is one integer value larger in each coordinate than the selected distribution.

At 606, the one or more processors tune the inductors based on the selected distribution, e.g., by programming each inductor to provide (or at least approximate) the tunable inductance provided for it in the selected distribution. Act 606 may be performed as part of act 510 of method 500.

### Computing Systems

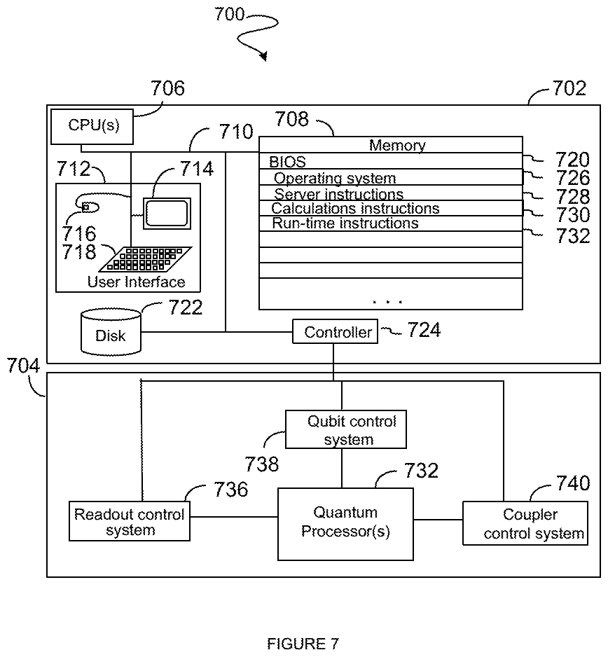

The foregoing methods may be performed by a hybrid computing system (e.g. comprising the foregoing analog computing systems). FIG. 7 illustrates an example hybrid computing system 700 including a digital computer 702 coupled to an analog computer 704. In some implementations, analog computer 704 is a quantum computer and digital computer 702 is a classical computer.

The exemplary digital computer 702 includes a digital processor (such as one or more central processor units 706) that may be used to perform classical digital processing tasks described in the present systems and methods. Those skilled in the relevant art will appreciate that the present systems and methods can be practiced with other digital computer configurations, including hand-held devices, multiprocessor systems, microprocessor-based or programmable consumer electronics, personal computers (“PCs”), network PCs, mini-computers, mainframe computers, and the like, when properly configured or programmed to form special purpose machines, and/or when communicatively coupled to control an analog computer, for instance a quantum computer.

Digital computer 702 will at times be referred to in the singular herein, but this is not intended to limit the application to a single digital computer. The present systems and methods can also be practiced in distributed computing environments, where tasks or sets of instructions are performed or executed by remote processing devices, which are linked through a communications network. In a distributed computing environment computer-readable and/or processor-readable instructions (sometimes known as program modules), application programs and/or data, may be stored in local and/or remote memory storage devices (e.g., non-transitory computer-readable and/or processor-readable media).

Digital computer 702 may include at least one or more digital processors (e.g., one or more central processor units 706), one or more system memories 708, and one or more system buses 710 that couple various system components, including system memory 708 to central processor unit 706.

The digital processor may be any logic processing unit, such as one or more central processing units (“CPUs”) with one or more cores, graphics processing units (“GPUs”), digital signal processors (“DSPs”), application-specific integrated circuits (“ASICs”), field-programmable gate arrays (“FPGAs”), programmable logic controllers (PLCs), etc.

Digital computer 702 may include a user input/output subsystem 712. In some implementations, the user input/output subsystem includes one or more user input/output components such as a display 714, mouse 716, and/or keyboard 718. System bus 710 can employ any known bus structures or architectures, including a memory bus with a memory controller, a peripheral bus, and a local bus. System memory 708 may include non-volatile memory, for example one or more of read-only memory (“ROM”), static random-access memory (“SRAM”), Flash NAND; and volatile memory, for example random access memory (“RAM”) (not shown), all of which are examples of non-transitory computer-readable and/or processor-readable media.

A basic input/output system (“BIOS”) 720, which can form part of the ROM, contains basic routines that help transfer information between elements within digital computer 702, such as during startup.

Digital computer 702 may also include other non-volatile memory 722. Non-volatile memory 722 may take a variety of forms, including: a hard disk drive for reading from and writing to a hard disk, an optical disk drive for reading from and writing to removable optical disks, and/or a magnetic disk drive for reading from and writing to magnetic disks, all of which are examples of non-transitory computer- or processor-readable media. The optical disk can be a CD-ROM or DVD, while the magnetic disk can be a magnetic floppy disk or diskette. Non-volatile memory 722 may communicate with digital processor via system bus 710 and may include appropriate interfaces or controllers 724 coupled to system bus 710. Non-volatile memory 722 may serve as non-transitory long-term storage for computer-readable and/or processor-readable instructions, data structures, or other data (also called program modules) for digital computer 702.

Although digital computer 702 has been described as employing hard disks, optical disks and/or magnetic disks, those skilled in the relevant art will appreciate that other types of non-volatile computer-readable media may be employed, such magnetic cassettes, flash memory cards, Flash, ROMs, smart cards, etc., all of which are further examples of non-transitory computer- or processor-readable media. Those skilled in the relevant art will appreciate that some computer architectures conflate volatile memory and non-volatile memory. For example, data in volatile memory can be cached to non-volatile memory, or a solid-state disk that employs integrated circuits to provide non-volatile memory. Some computers place data traditionally stored on disk in memory. As well, some media that are traditionally regarded as volatile can have a non-volatile form, e.g., Non-Volatile Dual In-line Memory Module variation of Dual In-Line Memory Modules.

Various sets of computer-readable and/or processor-readable instructions (also called program modules), application programs and/or data can be stored in system memory 708. For example, system memory 708 may store an operating system 726, server instructions 728, calculations instructions 730, and/or run-time instructions 732.

While shown in FIG. 7 as being stored in system memory 708, the program modules and other data can be stored elsewhere including in non-volatile memory 722 or in one or more other non-transitory computer-readable and/or processor-readable media.

Analog computer 704 can be provided in an isolated environment (not shown). For example, where analog computer 704 is a quantum computer, the environment shields the internal elements of the quantum computer from heat, magnetic field, and the like. Analog computer 704 includes one or more analog processors such as quantum processor(s) 734.

A quantum processor includes programmable elements such as qubits, couplers, and other devices. In one implementation, the qubits are superconducting flux qubits. The qubits are read out via readout system 736. These results can be fed to the various sets of computer-readable and/or processor-readable instructions for digital computer 702. Analog computer 704 can include a qubit control system 738 and a coupler control system 740. Coupler control system 740 can provide control of communicative coupling between qubits such as inductive and capacitive communicative coupling described in the present application.

In some embodiments, hybrid computer 700 is used to implement quantum annealing on quantum processor 734.

In some implementations, digital computer 702 can operate in a networked environment using logical connections to at least one client computer system. In some implementations, digital computer 702 is coupled via logical connections to at least one database system. These logical connections may be formed using any means of digital communication, for example, through a network, such as a local area network (“LAN”) or a wide area network (“WAN”) including, for example, the Internet. The networked environment may include wired or wireless enterprise-wide computer networks, intranets, extranets, and/or the Internet. Other embodiments may include other types of communication networks such as telecommunications networks, cellular networks, paging networks, and other mobile networks. The information sent or received via the logical connections may or may not be encrypted. When used in a LAN networking environment, digital computer 702 may be connected to the LAN through an adapter or network interface card (“NIC”) (communicatively linked to system bus 710). When used in a WAN networked environment, digital computer 702 may include an interface and modem (not shown), or a device such as NIC, for establishing communications over the WAN. Non-networked communications may additionally, or alternatively, be employed.

In accordance with some embodiments of the present systems and devices, a quantum processor (such as quantum processor 734 of FIG. 7) may be designed to perform quantum annealing and/or adiabatic quantum computation. An evolution Hamiltonian is constructed, that is proportional to the sum of a first term proportional to a problem Hamiltonian and a second term proportional to a delocalization Hamiltonian, as follows:

H_{E}∝A(t)H_{P}+B(t)H_{D}
where H_{E} is the evolution Hamiltonian, H_{P} is the problem Hamiltonian, H_{D} is the delocalization Hamiltonian, and A(t), B(t) are coefficients that can control the rate of evolution, and typically lie in the range [0,1].

In some implementations, a time-varying envelope function is placed on the problem Hamiltonian. A suitable delocalization Hamiltonian is given by:

$${H}_{D} ∝ - \frac{1}{2} {\sum }_{i = 1}^{N} {Δ}_{i} {σ}_{i}^{x}$$

where N represents the number of qubits,

$${σ}_{i}^{x}$$

is the Pauli x-matrix for the i^{th} qubit and Δᵢ is the single qubit tunnel splitting induced in the i^{th} qubit. Here, the

$${σ}_{i}^{x}$$

terms are examples of “off-diagonal” terms.

A common problem Hamiltonian includes a first component proportional to diagonal single qubit terms, and a second component proportional to diagonal multi-qubit terms, and may be of the following form:

$${H}_{P} ∝ - \frac{ε}{2} [ {\sum }_{i = 1}^{N} {h}_{i} {σ}_{i}^{z} + {\sum }_{j > 1}^{N} {J}_{ij} {σ}_{i}^{z} {σ}_{j}^{z} ]$$

where N represents the number of qubits,

$${σ}_{i}^{z}$$

is the Pauli z-matrix for the i^{th} qubit, hᵢ and Jᵢⱼ are dimensionless local fields for the qubits, and couplings between qubits, respectively, and ε is a characteristic energy scale for H_{P}. The

$${σ}_{i}^{z} and {σ}_{i}^{z} {σ}_{j}^{z}$$

terms and examples of “diagonal” terms. The former is a single-qubit term and the latter a two-qubit term.

Homogenizing inductance and/or capacitance across programmable states of an individual qubit, and/or across qubits across a quantum processor, can assist in homogenizing their physical behaviour. Such homogenization of the underlying physics can, in suitable circumstances, enable the quantum processor to more accurately instantiate the foregoing computational models, thereby improving the performance of the quantum processor and consequently of hybrid computing system 700 more generally.

### Butterfly Qubits

As discussed above, superconducting flux qubits (for example superconducting flux qubit 100a) may include a loop of superconducting material (e.g., qubit loop 102) interrupted by a Josephson junction (e.g., CJJ 104). Qubits are connected by couplers (e.g., coupler 222) within a quantum processor, and the type and complexity of problems that may be solved by the processor may be impacted by the connectivity between qubits. In some implementations, increasing connectivity between single loop flux qubits (e.g., flux qubit 100a, 201) is realized at least in part by increasing the length of the qubit to accommodate the additional couplers. Increased qubit length may result in increased inductance and capacitance and a corresponding reduction in energy scale. In some implementations, it may be beneficial to provide a multi-loop flux qubit (e.g., qubit 401) as discussed above with respect to FIGS. 4A and 4B and in further detail below. Multi-loop flux qubits may allow for increased connectivity without a corresponding decrease in energy scale.

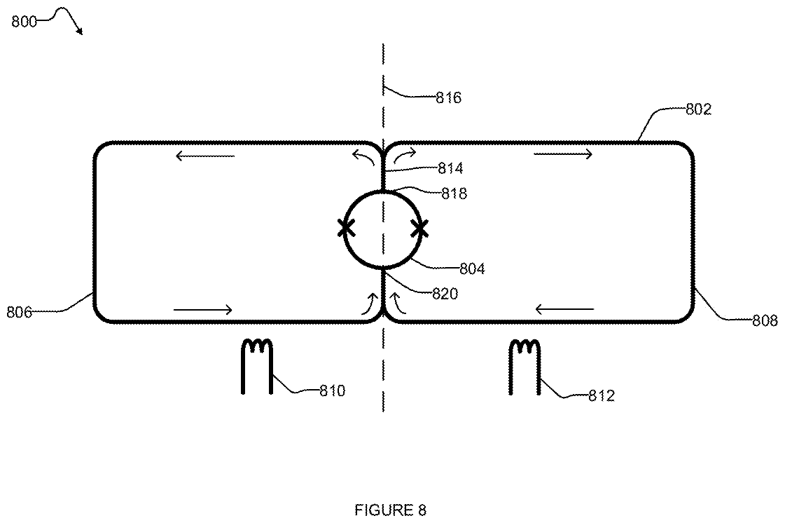

In the example implementation of FIG. 8, an analog computing system 800 has a qubit 802 with a Josephson junction 804, a first qubit loop 806 formed by a first superconducting current path, and a second qubit loop 808 formed by a second superconducting current path. First qubit loop 806 and second qubit loop 808 are electrically connected in parallel across Josephson junction 804. A qubit with two loops may also be referred to as a two wing qubit or butterfly qubit, each of the loops constituting one of the wings. In the example implementation of FIG. 8, first qubit loop 806 and second qubit loop 808 are symmetric about axis 816 of Josephson junction 804, axis 816 intersecting first connection 818 between first and second qubit loops 806, 808 and Josephson junction 804 and second connection 820 between first and second qubit loops 806, 808 and Josephson junction 804. From the perspective of the Josephson junction, a two wing qubit will behave in the same manner as an RF SQUID flux qubit, such as those in FIGS. 1A and 1B. At zero applied flux, the magnitude of current flowing in each wing will be half of what flows through the Josephson junction. The persistent current flowing through the junction is split when flowing into the parallel wings, such that the total persistent current through the junction is the combination of the persistent current flowing in each wing. The total effective body inductance will be equal to the parallel combination of the inductances of the two wings. In the implementation of FIG. 8, the rotational direction of current flow will be opposite between the two wings. In the example implementation of FIG. 8, the Josephson junction is a compound Josephson junction. In other implementations it may be a compound-compound Josephson junction, which refers to a compound Josephson junction where at least one junction is also a compound Josephson junction.

Independent control of each wing of qubit 802 may be provided by a flux bias source, such as flux bias lines that externally apply bias current to the qubit loops. First qubit loop 806 may be in communication with a first flux bias line 810, and second qubit loop 808 may be in communication with a second flux bias line 812. First flux bias line 810 may receive signals independently from second flux bias line 812, allowing for independent control of each qubit loop. As discussed above, first qubit loop 806 and second qubit loop 808 may partially overlap along a shared portion 814. The two wings 806, 808 of qubit 802 allow two different current paths, one with the current flowing through the Josephson junction and into the wings, which responds to the difference in flux bias between the wings, and the second with the current flowing only around the outer loop formed by the two wings, which responds to the sum of flux in the wings.

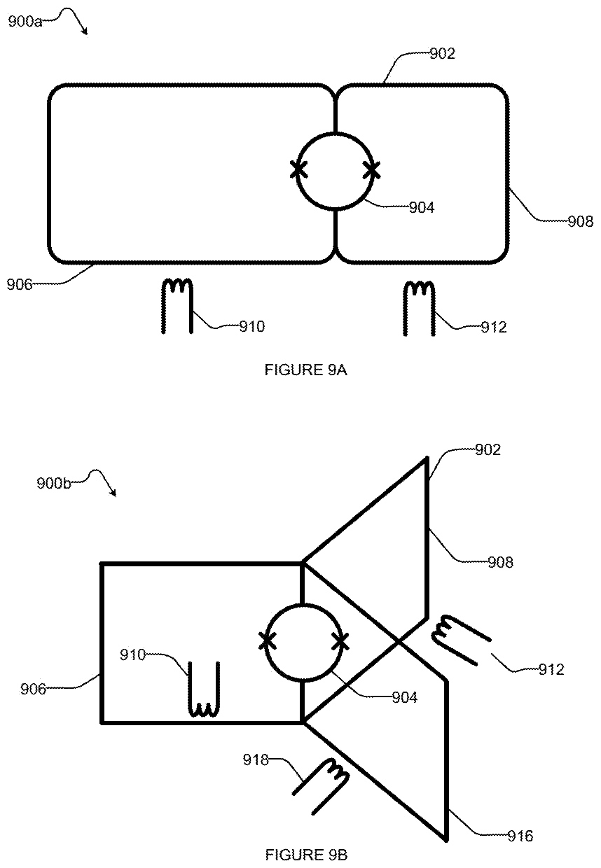

In the example implementation of FIG. 9A, analog computing system 900a has a qubit 902 with a Josephson junction 904. In contrast with FIG. 8, where first qubit loop 806 and second qubit loop 808 are symmetric, in FIG. 9A, first qubit loop 906 and second qubit loop 908 are asymmetric. First and second flux bias lines 910 and 912 are in communication with first and second qubit loops 906 and 908. In the example implementation of FIG. 9B, analog computing system 900b has a qubit 902 with a Josephson junction 904, first and second qubit loops 906 and 908, and first and second flux bias lines 910 and 912. In FIG. 9B, an additional qubit loop 916 is electrically connected in parallel across Josephson junction 904 and has independent flux bias line 918. In other implementations, qubits may be designed with one or more additional qubit loops, and additional wings may be added in parallel. Increasing the number of wings may result in scaling of the potential energy of the entire qubit by a factor proportional to the number of wings.

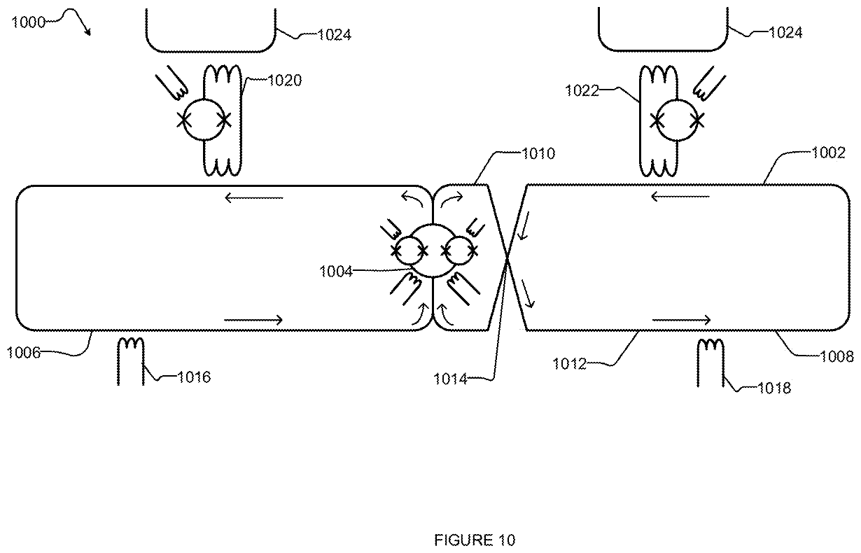

In the example implementation of FIG. 10, an analog computing system 1000 has a qubit 1002 with a compound-compound Josephson junction (CCJJ) 1004, a first qubit loop 1006 formed by a first superconducting current path, and a second qubit loop 1008 formed by a second superconducting current path. First qubit loop 1006 and second qubit loop 1008 are electrically connected in parallel across Josephson junction 1004. Second qubit loop 1002 has a first portion 1010 in communication with Josephson junction 1004, a second portion 1012 spaced from Josephson junction 1004, and a crossing 1014 separating first portion 1010 and second portion 1012. Current in first portion 1010 travels in a first rotational direction (e.g., illustrated as clockwise), and current in second portion 1012 travels in a second rotational direction (e.g., illustrated as counterclockwise) that is opposite to the first rotational direction. It will be understood that the orientation shown in the example implementation of FIG. 10 may be reversed, such that the first rotational direction is counterclockwise and the second rotational direction is clockwise. It will be understood that the crossing acts as a “twist” in the second qubit loop and may be formed by the superconducting material crossing in layers that are spaced orthogonally (e.g., vertically) apart in a multi-layer circuit. Providing a twist in one wing of the qubit may allow the entire qubit to act like a longer single loop qubit without a twist. The twist in one wing may homogenize the sense of persistent current within the circuit. As shown in FIG. 10, while the current directions are reversed near the CCJJ, the current travelling through the outer portions of the qubit is generally counterclockwise.

Analog computing system 1000 further has first flux bias line 1016 and second flux bias line 1018, as well as first coupler 1020 and second coupler 1022 tunably coupled to first qubit loop 1006 and second qubit loop 1008 respectively. In other implementations an analog computing system may have one or more than two couplers tunably coupled to one of a first qubit loop and a second qubit loop. First coupler 1020 and second coupler 1022 may couple qubit 1002 to another qubit 1024, or to multiple other qubits or other devices. Couplings may be made to neighboring qubits along the length of the wings. By decreasing the wing length as additional wings are added, connectivity may be increased for the same energy scale. Conversely, for a fixed connectivity, the energy scale may be increased by decreasing the wing length and increasing the number of wings.

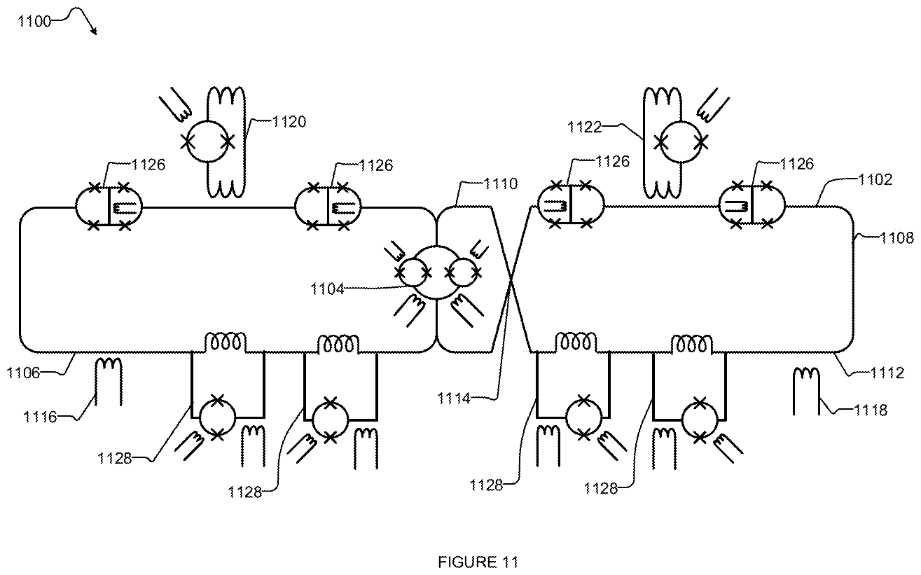

In the example implementation of FIG. 11, an analog computing system 1100 has qubit 1102, CCJJ 1104, first qubit loop 1106, and second qubit loop 1108. Second qubit loop 1108 has a first portion 1110, a second portion 1112, and a crossing 1114. Qubit 1102 is similar to qubit 1002, with additional devices in communication with qubit loops 1106 and 1108 beyond flux bias lines 1116 and 1118 and couplers 1120 and 1122. This includes a plurality of inductors 1126 disposed along each of first qubit loop 1106 and second qubit loop 1108, each of the plurality of inductors 1126 being tunable to provide a corresponding tunable inductance, as discussed in detail above. Also shown are persistent current compensators 1128, which may be coupled to a signal line and provide a variety of waveforms as discussed in U.S. Pat. No. 9,015,215 (compensators referred to therein as multipliers). The qubits described herein may include other devices such as programming, readout, and calibration devices, and may also include other quantities of the devices shown.

It will be understood that the structures shown in FIGS. 10 and 11 are example implementations of butterfly qubits. For example, Josephson junction 1004 is shown as a compound-compound Josephson junction, but may also be a compound Josephson junction with one junction on each side of the loop or may have other numbers of junctions. The bias lines shown may provide independent biases, or they may be connected in series and driven by a single source. The biases provided to either side of the loop may be the same, or different biases may be provided. Each bias shown, including biases 1016 and 1018, as well as bias lines connected to the Josephson junctions and couplers, may be provided by more than one bias. For example, in some implementations, each bias line shown may be provided by two independent lines, with one line being driven by an external room-temperature source, and one being driven by an on-chip Digital-to-Analog Converter (DAC). As discussed above, these are example implementations, and the circuit may not include all of the devices shown, may include other devices such as programming, readout, and calibration devices, and may include other quantities of the devices shown.

The methods (500, 600) described above may be used with the qubits (802, 902, 1002, and 1102) described above.

Throughout this specification, the terms “problem Hamiltonian” and “final Hamiltonian” are used interchangeably unless the context dictates otherwise. Certain states of the quantum processor are, energetically preferred, or simply preferred by the problem Hamiltonian. These include the ground states but may include excited states.

Hamiltonians such as H_{D} and H_{P} in the above two equations, respectively, may be physically realized in a variety of different ways. A particular example is realized by an implementation of superconducting qubits.

Examples of superconducting qubits include superconducting flux qubits, superconducting charge qubits, and the like. In a superconducting flux qubit, the Josephson energy dominates or is equal to the charging energy. In a charge qubit it is the reverse. Examples of flux qubits that may be used include RF-SQUIDs, which include a superconducting loop interrupted by one Josephson junction, persistent current qubits, which include a superconducting loop interrupted by three Josephson junctions, and the like. See, examples of RF-SQUID qubits in Bocko, et al., 1997, IEEE Trans. on Appl. Supercond. 7, 3638; Friedman, et al., 2000, Nature 406, 43; and Harris, et al., 2010, Phys. Rev. B 81, 134510; or persistent current qubits, Mooij et al., 1999, Science 285, 1036; and Orlando et al., 1999, Phys. Rev. B 60, 15398. In addition, hybrid charge-phase qubits, where the energies are equal, may also be used. Further details of superconducting qubits may be found in Makhlin, et al., 2001, Rev. Mod. Phys. 73, 357; Devoret et al., 2004, arXiv: cond-mat/0411174; Zagoskin and Blais, 2007, Physics in Canada 63, 215; Clarke and Wilhelm, 2008, Nature 453, 1031; Martinis, 2009, Quantum Inf. Process. 8, 81; and Devoret and Schoelkopf, 2013, Science 339, 1169. In some embodiments, the qubits and couplers are controlled by on chip circuitry. Examples of on-chip control circuitry can be found in U.S. Pat. Nos. 7,876,248; 7,843,209; 8,018,244; 8,098,179; 8,169,231; and 8,786,476. Further details and implementations of exemplary quantum processors that may be used in conjunction with the present systems and devices are described in, for example, U.S. Pat. Nos. 7,533,068; 8,008,942; 8,195,596; 8,190,548; and 8,421,053.

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for exemplary purposes only and may change in alternative examples. Some of the exemplary acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the exemplary methods for quantum computation generally described above.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to: U.S. Pat. Nos. 7,135,701; 7,418,283; 8,536,566; 9,015,215; 9,152,923; PCT Application No. US2018/066613; and U.S. Patent Application No. 62/951,738.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1-45. (canceled)

46. A quantum processor comprising:
a plurality of qubits, each qubit comprising:
a Josephson junction;
a first qubit loop formed by a first superconducting current path;
a second qubit loop formed by a second superconducting current path, the second qubit loop comprising a first portion in communication with the Josephson junction and a second portion spaced from the Josephson junction, the first portion and the second portion being separated by a crossing, the crossing comprising the second superconducting current path overlying itself in wiring layers that are spaced apart;
the first qubit loop and the second qubit loop electrically connected in parallel across the Josephson junction; and
wherein a current in the second qubit loop travels in a first rotational direction in the first portion and a second rotational direction that is opposite to the first rotational direction in the second portion such that the current travelling through an outer current path comprising the first qubit loop and the second portion of the second qubit loop travels in a same rotational direction.

47. The quantum processor of claim 46, further comprising a first flux bias line in communication with the first qubit loop and a second flux bias line in communication with the second qubit loop, the first flux bias line receiving signals independently from the second flux bias line to realize independent control of each of the first qubit loop and the second qubit loop.

48. (canceled)

49. The quantum processor of claim 46, wherein the Josephson junction comprises one of a compound Josephson junction or a compound-compound Josephson junction.

50. The quantum processor of claim 46, wherein the first qubit loop and the second qubit loop partially overlap along a shared portion.

51. The quantum processor of claim 46, further comprising a coupler tunably coupled to one of the first qubit loop and the second qubit loop.

52. The quantum processor of claim 51, further comprising a second qubit coupled to the coupler.

53. (canceled)

54. The quantum processor of claim 46, further comprising one or more additional qubit loops electrically connected in parallel across the Josephson junction.

55. The quantum processor of claim 46, further comprising a plurality of inductors disposed along each of the first qubit loop and the second qubit loop, each of the plurality of inductors being tunable to provide a corresponding tunable inductance.

56. The quantum processor of claim 46, wherein the plurality of qubits comprises a first pair of qubits and a first coupler, the first coupler coupling the first qubit loop of a first qubit of the pair of qubits to a first qubit loop of a second qubit of the pair of qubits.

57. The quantum processor of claim 46, further comprising at least one additional qubit and at least one additional coupler, wherein the at least one additional coupler couples the second qubit loop of the first qubit to the at least one additional qubit.

58. The quantum processor of claim 46, further comprising at least one first device coupled to the first qubit loop and at least one second device coupled to the second qubit loop, the first device and the second device each comprising at least one of a persistent current compensator, a programming device, a readout device, and a calibration device.

59. The quantum processor of claim 46, further comprising at least one on-chip Digital-to-Analog Converter (DAC) coupled to provide a flux bias to at least one of the first qubit loop and the second qubit loop.

60. The quantum processor of claim 46, wherein the plurality of qubits comprises a first qubit having a first qubit loop coupled to a first coupler and a second coupler, a second qubit loop coupled to the first coupler, and a third qubit coupled to the second coupler.

61. The quantum processor of claim 46, wherein the second superconducting current path is formed in a first layer and a second layer spaced orthogonally from the first layer and separated by a dielectric layer.
